(19) United States
(12) Patent Application Publication
(10) Pub. No.: US 2024/0038836 A1
(43) Pub. Date: Feb. 1, 2024

(54) SYSTEMS AND METHODS FOR FABRICATING CROSS-PILLAR SUPERJUNCTION STRUCTURES FOR SEMICONDUCTOR POWER CONVERSION DEVICES

(71) Applicant: General Electric Company, Schenectady, NY (US)

(72) Inventors: Collin William Hitchcock, Clifton Park, NY (US); Reza Ghandi, Cohoes, NY (US)

(21) Appl. No.: 17/878,655

(22) Filed: Aug. 1, 2022

(51) Int. Cl. H01L 29/06; H01L 29/78; H01L 21/266; H01L 29/66; H01L 29/16

(52) U.S. Cl. CPC H01L 29/0634; H01L 29/7813; H01L 29/0696; H01L 21/266; H01L 29/66712; H01L 29/1608

(57) ABSTRACT

A semiconductor device includes a first epitaxial (epi) layer that forms a first super-junction (SJ) layer of the semiconductor device and a second epi layer disposed on the first SJ layer that forms a device layer of the semiconductor device. The first epi layer includes oppositely doped SJ pillars that extend along a first direction within the SJ layer. The device layer includes device structures of a striped metal-oxide-semiconductor field-effect transistor (MOSFET) device cell that extends along a second direction within the device layer. The angle between the first direction and the second direction is substantially between forty-five degrees and ninety degrees, inclusive.

### GOVERNMENT LICENSE RIGHTS

This invention was made with government support under DE-AR0001007 awarded by ARPA-E. The government has certain rights in the invention.

### BACKGROUND

The subject matter disclosed herein relates to semiconductor power conversion devices, such as metal-oxide-semiconductor field-effect transistor (MOSFET) devices, and, more specifically, to super-junction (SJ) MOSFET devices.

For semiconductor power conversion devices, SJ structures offer several advantages. For example, a SJ structure may help reduce on-state resistance of a semiconductor power conversion device and resultant on-state conduction losses of the semiconductor power conversion device while demonstrating a higher block voltage relative to traditional unipolar device designs. However, in semiconductor power conversion devices, such as MOSFET devices, both the surface structures (e.g., certain MOSFET device layer features) and the SJ structures of the semiconductor power conversion devices have a natural periodicity to their respective structure designs that are dependent on the fabrication process and performance considerations. In certain situations, this can result in a pitch mismatch between the surface structures and the SJ structures, thereby increasing on-state resistance of the semiconductor power conversion devices. Accordingly, it may be desirable to develop a process for fabricating the semiconductor power conversion devices to provide optimum matching between the surface structures of the semiconductor power conversion devices and the SJ structures of the semiconductor power conversion devices.

### BRIEF DESCRIPTION

In an embodiment, a semiconductor device includes a first epitaxial (epi) layer that forms a first super-junction (SJ) layer of the semiconductor device and a second epi layer disposed on the first SJ layer that forms a device layer of the semiconductor device. The first epi layer includes oppositely doped SJ pillars that extend along a first direction within the SJ layer. The device layer includes device structures of a striped metal-oxide-semiconductor field-effect transistor (MOSFET) device cell that extends along a second direction within the device layer. The angle between the first direction and the second direction is substantially between forty-five degrees and ninety degrees, inclusive.

In another embodiment, a method of fabricating a semiconductor device includes forming a first super-junction (SJ) layer of the semiconductor device and forming a device layer of the semiconductor device. The first SJ layer is formed by forming a first epitaxial (epi) layer on an underlying layer, implanting the first epi layer with a first set of SJ pillars to have a particular doping concentration of a first conductivity type, and implanting the first epi layer with a second set of SJ pillars to have the particular doping concentration of a second conductivity type. The first set of SJ pillars and the second set of SJ pillars extend along a first direction within the SJ layer. The device layer of the semiconductor device is formed by forming a second epi layer on the first SJ layer and forming device structures of a plurality of striped metal-oxide-semiconductor field-effect transistor (MOSFET) device cells in the device layer that extend along a second direction within the device layer. The angle between the first direction and the second direction is substantially between forty-five degrees and ninety degrees, inclusive.

In another embodiment, a semiconductor device includes a first epitaxial (epi) layer that forms a first super-junction (SJ) layer of the semiconductor device and a second epi layer disposed on the first SJ layer that forms a device layer of the semiconductor device. The first epi layer includes a first set of SJ pillars having a particular doping concentration of the first conductivity type and a second set of SJ pillars having the particular doping concentration of the second conductivity type. The first set of SJ pillars and the second set of SJ pillars extend along a first direction within the SJ layer. The device layer includes device structures of a plurality of striped metal-oxide-semiconductor field-effect transistor (MOSFET) device cells that extend along a second direction within the device layer. The angle between the first direction and the second direction is substantially between forty-five degrees and ninety degrees, inclusive.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is a top-down view of a portion of a typical semiconductor power conversion device including a number of striped metal-oxide-semiconductor field-effect transistor (MOSFET) device cells, in accordance with aspects of the present technique;

FIG. 2 is a cross-sectional view of the typical semiconductor power conversion device of FIG. 1, in accordance with aspects of the present technique;

FIG. 3 is a top-down view of an embodiment of a semiconductor power conversion device including a number of striped MOSFET device cells having an SJ structure angled orthogonally with respect to respective surface structures, in accordance with aspects of the present technique;

FIGS. 4A, 4B, 4C, and 4D are respective three-dimensional (3D) cross-sections of the embodiment of the semiconductor power conversion device of FIG. 3, in accordance with aspects of the present technique; and

FIG. 5 is a flow chart of a process for manufacturing an embodiment of a semiconductor power conversion device including a number of striped MOSFET device cells having respective SJ structures angled with respect to respective surface structures, in accordance with aspects of the present technique.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Unless defined otherwise, technical and scientific terms used herein have the same meaning as is commonly understood by one of ordinary skill in the art to which this disclosure belongs. The terms “first”, “second”, and the like, as used herein do not denote any order, quantity, or importance, but rather are used to distinguish one element from another. Also, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. If ranges are disclosed, the endpoints of all ranges directed to the same component or property are inclusive and independently combinable. The modifier “about” used in connection with a quantity is inclusive of the stated value and has the meaning dictated by the context (e.g., includes the degree of process variations or errors associated with measurement of the particular quantity). The modifier “substantially,” when used in combination with a descriptive term, is intended to convey that the descriptive terms mostly, mainly, or predominately apply (e.g., applies to greater than 90%, greater than 95%, or greater than 99% of the time), and may be used to account for limited exceptions that may result from process variations and technical limitations understood by those of the art.

As used herein, the term “layer” refers to a material disposed on at least a portion of an underlying surface in a continuous or discontinuous manner. Further, the term “layer” does not necessarily mean a uniform thickness of the disposed material, and the disposed material may have a uniform or a variable thickness. Furthermore, the term “a layer” as used herein refers to a single layer or a plurality of layers, unless the context clearly dictates otherwise. The term “adjacent” as used herein means that the two layers or features are disposed contiguously and in direct contact with each other. In the present disclosure, when a layer/device is being described as “on” another layer or substrate, it is to be understood that the layers/devices can either be directly contacting each other or have one (or more) layer or feature between the layers and devices. Further, the term “on” describes the relative position of the layers/devices to each other and does not necessarily mean “on top of” since the relative position above or below depends upon the orientation of the device to the viewer. Moreover, the use of “top,” “bottom,” “above,” “below,” “upper”, “buried” and variations of these terms is made for convenience and does not require any particular orientation of the components unless otherwise stated. With this in mind, as used herein, the terms “lower,” “buried,” “middle,” or “bottom” refer to a feature (e.g., epitaxial layer, termination area) that is relatively nearer the substrate layer, while the terms “top” or “upper” refer to the particular feature (e.g., epitaxial layer, termination area) that is relatively the farthest from the substrate layer.

Present embodiments are directed toward designs and methods for manufacturing semiconductor power conversion devices, such as silicon carbide super-junction (SiC-SJ) power devices. The disclosed designs and methods are useful in the manufacture of SJ devices, such as metal-oxide-semiconductor field-effect transistors (MOSFETs) as well as other SJ devices that may be useful for medium-voltage (e.g., 2 kV-10 kV) and high-voltage (e.g., greater than or equal to 10 kV) power conversion related applications. While discussed in the context of a planar MOSFET device below, it may be appreciated that the disclosed technique may be applicable to other suitable types of semiconductor devices, such as trench MOSFETs or the like. As discussed below, the disclosed semiconductor power conversion device designs include multi-layered drift regions implemented using repeated epitaxial growth and dopant implantation steps. As used herein, the term “multi-layered,” as well as references to a particular number of layers, for example, “two-layered,” “three-layered,” “four-layered,” refer to the number of epitaxial layers, also referred to herein as epi layers.

More specifically, present embodiments are directed toward designs and methods for manufacturing semiconductor power conversion devices, such as MOSFETs. As mentioned above, super-junction (SJ) structures for semiconductor power conversion devices offer several advantages. For example, a SJ structure may help reduce on-state resistance of a semiconductor power conversion device and resultant on-state conduction losses of the semiconductor power conversion device while demonstrating a higher block voltage relative to traditional unipolar device designs. However, in semiconductor power conversion devices, such as MOSFET devices, both the surface structures (e.g., certain MOSFET device layer features) and the SJ structures of the semiconductor power conversion devices have a natural periodicity to their respective structure designs that are dependent on the fabrication process and performance considerations. In certain situations, this can result in a pitch mismatch between the surface structures and the SJ structures, thereby increasing on-state resistance of the semiconductor power conversion devices. Accordingly, the disclosed MOSFET designs arrange the SJ structures relative to the surface structures of the semiconductor power conversion devices in a manner that enables improved (e.g., enhanced, optimized) matching between the surface structures of the semiconductor power conversion devices and the SJ structures of the semiconductor power conversion devices.

As discussed in detail below, present embodiments are directed towards semiconductor power conversion device designs that include a device epitaxial (epi) layer having device features of striped MOSFET device cells oriented in a first direction, and include one or more underlying SJ layers having SJ structures (e.g., SJ pillars) oriented in a second direction, wherein an angle between the first direction and the second direction is substantially between forty-five degrees and ninety degrees, inclusive. For instance, in one embodiment, the surface features of the device epi layer may be oriented substantially orthogonally (e.g., at a ninety degree angle) to the SJ structures of the one or more underlying SJ layers. In this way, a pitch of the semiconductor power conversion device is reduced, as compared to a pitch of a semiconductor power conversion device in which the surface features of the striped MOSFET device cells are oriented in the same direction as (e.g., oriented parallel to) the SJ structures of the one or more underlying SJ layers. As such, a channel density of the semiconductor power conversion device is increased, thereby decreasing the on-state resistance of the semiconductor power conversion device during an on-state operation.

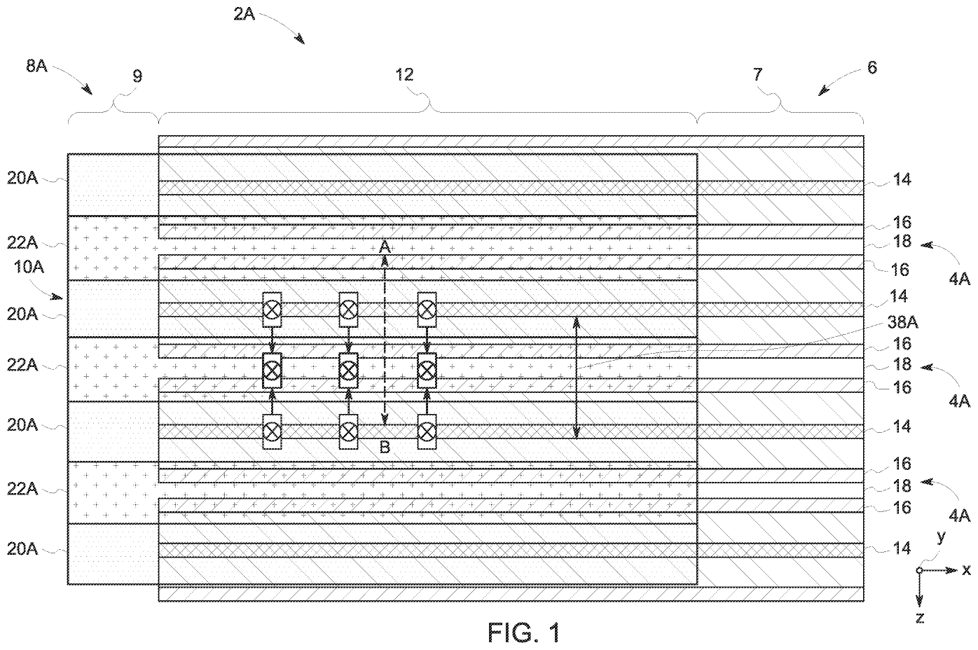

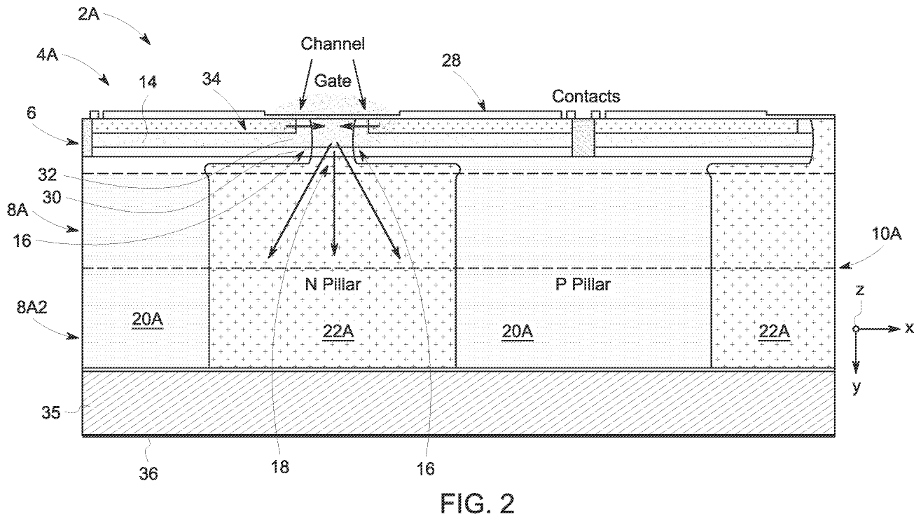

With the foregoing in mind, FIG. 1 illustrates a top-down view of a portion of a typical semiconductor power conversion device 2A including a number of striped MOSFET device cells 4A. Additionally, FIG. 2 illustrates a cross-sectional view of the portion of the typical semiconductor power conversion device 2A of FIG. 1 along the dashed line A-B. As illustrated in FIG. 1, the power conversion device 2A includes a device epi layer 6 and an underlying SJ layer 8A. In particular, a first section 7 (e.g., the right-most section) of FIG. 1 illustrates various device structures (e.g., surface structures) of the device epi layer 6, a second section 9 (e.g., the left-most section) of FIG. 1 illustrates a SJ structure 10A of the underlying SJ layer 8A, and a third section 12 (e.g., the middle section) of FIG. 1 illustrates both the device structures of the device epi layer 6 and the SJ structure 10A of the underlying SJ layer 8A. The device structures of the device epi layer 6 are illustrated as being partially transparent in the third section 12 in order to illustrate the alignment between the SJ structure 10A of the underlying SJ layer 8A with the device structures of the device epi layer 6.

The device structures of the device epi layer 6 of each striped MOSFET device cells 4A include respective contact regions 14, respective channel regions 16, and respective junction field-effect transistor (JFET) regions 18. It may be appreciated that the contact regions 14, the channel regions 16, and the JFET regions 18 are formed as continuous stripes along the surface of the striped MOSFET device cells 4A. Additionally, the SJ structure 10A of the underlying SJ layer 8A below each striped MOSFET device cell 4A includes a first set of implanted SJ pillars 20A oppositely doped relative to a second set of implanted SJ pillars 22A. As illustrated in FIG. 1, the features of the striped MOSFET device cells 4A disposed in the device epi layer 6 extend in a direction (i.e., along the x-axis), and the SJ pillars 20A and 22A of the underlying SJ layer 8A also extend in the same direction (i.e., along the x-axis). That is, while disposed in different x-z planes, the features of the striped MOSFET device cells 4A (e.g., the contact regions 14, the channel regions 16, and the JFET regions 18) are oriented substantially parallel to the SJ pillars 20A and 22A within the semiconductor power conversion device 2A.

As illustrated in FIG. 2, the semiconductor power conversion device 2A includes a number of epi layers in which the striped MOSFET device cells 4A are defined. These include device epi layer 6 and underlying SJ layers 8A, 8A2. While the illustrated embodiment includes three epi layers, in other embodiments, the semiconductor power conversion device 2A may include any suitable number of epi layers (e.g., two, three, four, five, six, or more) to yield a device having a particular desired voltage rating. The epi layers may be fabricated using repeated cycles of epitaxial overgrowth. As illustrated in FIG. 2, the SJ layer 8A2 is formed and disposed directly on a substrate layer 35, the SJ layer 8A is formed and disposed directly on the SJ layer 8A2, and the device epi layer 6 is formed and disposed directly on the SJ layer 8A. In some embodiments, the semiconductor power conversion device 2A may include additional epi layers, including any suitable number of SJ layers, intervening between the device epi layer 6 and the SJ layer 8A and/or disposed below the SJ layer 8A.

A top surface 28 of the device epi layer 6 includes a well region 30 having a first conductivity type (e.g., a p-type well region 30) disposed adjacent to a source region 32 having a second conductivity type (e.g., a n-type source region 32) of an exemplary striped MOSFET device cell 4A. Additionally, a source contact 34 of the striped MOSFET device cell 4A is disposed adjacent to the top surface 28 of the device epi layer 6 (e.g., in the contact region 14), and is disposed on a portion of both the well region 30 and the source region 32 of the device epi layer 6. During an on-state operation of the striped MOSFET device cell 4A, an appropriate gate voltage (e.g., at or above a threshold voltage (V_{TH}) of the striped MOSFET device cell 4A) causes respective inversion layers to form in the respective channel regions 16 of the striped MOSFET device cell 4A, as well as respective conductive paths to be enhanced in the respective JFET regions 18 of the device cell due to accumulation of carriers, allowing current to flow between respective drain contacts 36 (e.g., a drain electrode), a drain terminal) of the device cell and the respective source contacts 34 (e.g., a source electrode, a source terminal) of the device cell. The channel region 14 of the striped MOSFET device cell 4A may be generally defined as an upper portion of the well region 30 below the top surface 28 of the device cell. As mentioned above, the first set of implanted SJ pillars 20A and the oppositely doped second set of implanted SJ pillars 22A are disposed below the surface features of the striped MOSFET device cell 4A disposed in the device epi layer 6. The first set of implanted SJ pillars 20A and the second set of implanted SJ pillars 22A are disposed in the underlying SJ layer 8A such that the first set of implanted SJ pillars 20A and the second set of implanted SJ pillars 22A are substantially parallel to the device structures (e.g., the contact region 14, the channel region 16, the JFET region 18, and the source contact 34) of the striped MOSFET device cell 4A (i.e., both oriented along the x-axis).

Accordingly, during the on-state operation of each striped MOSFET device cell 4A (e.g., for a p-channel MOSFET device cell), current flows from the source contact 34 of the striped MOSFET device cell 4A to the drain contact 36 of device cell through the second set of implanted SJ pillars 22A. That is, as illustrated in FIGS. 1 and 2, the current flows from the source contact 34 to the channel region 16 along the top surface 28 of the striped MOSFET device cell 4A, from the channel region 16 into an implanted SJ pillar 22A (e.g., n-type SJ pillar 22A), and from the implanted SJ pillar 22A to the drain contact 36 of the semiconductor power conversion device 2A. Further, it should be noted that, for a n-channel MOSFET device cell, the current may flow from the drain contact 36 of the striped MOSFET device cell 4A to the source contact 34 of the striped MOSFET device cell 4A. That is, the current may flow in the opposite direction with respect to the current described above during an on-state operation of a p-channel MOSFET device cell.

However, as mentioned above, due to the natural periodicity of the respective designs of the device structures (e.g., the contact region 14, the channel region 16, the JFET region 18, and the source contact 34) of the device epi layer 6 of the semiconductor power conversion device 2A and the SJ structures (e.g., the first set of implanted SJ pillars 20A and the second set of implanted SJ pillars 22A) of one or more SJ layers 8A, 8A2, a mismatch between the device structures and the SJ structures may occur during fabrication. This mismatch can result in an increase in a pitch 38A between subsequent device structures (e.g., the contact region 14, the channel region 16, the JFET region 18, and the source contact 34) of the device epi layer 6 of the typical semiconductor power conversion device 2A (e.g., as compared to the embodiments described below), thereby undesirably decreasing a channel density of the typical semiconductor power conversion device 2A and increasing an on-state resistance of the typical semiconductor power conversion device 2A.

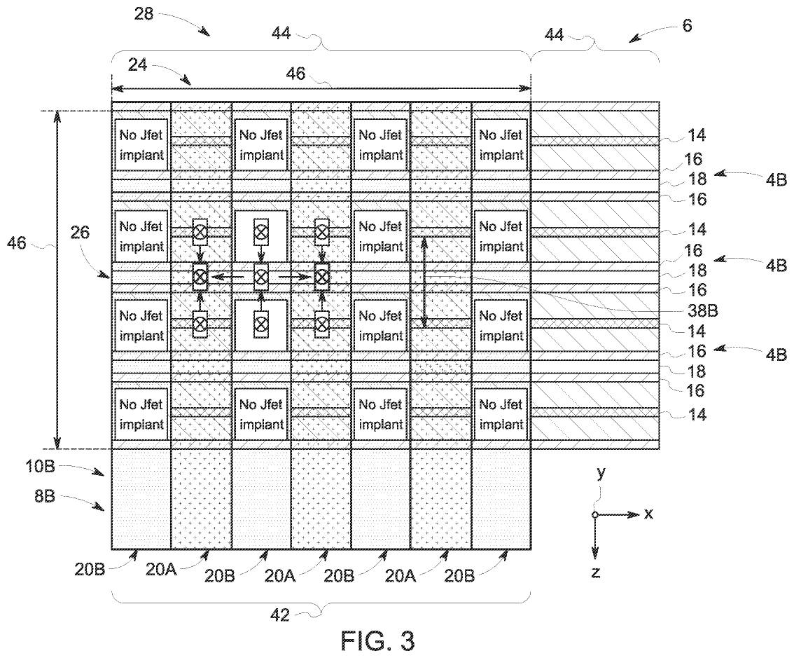

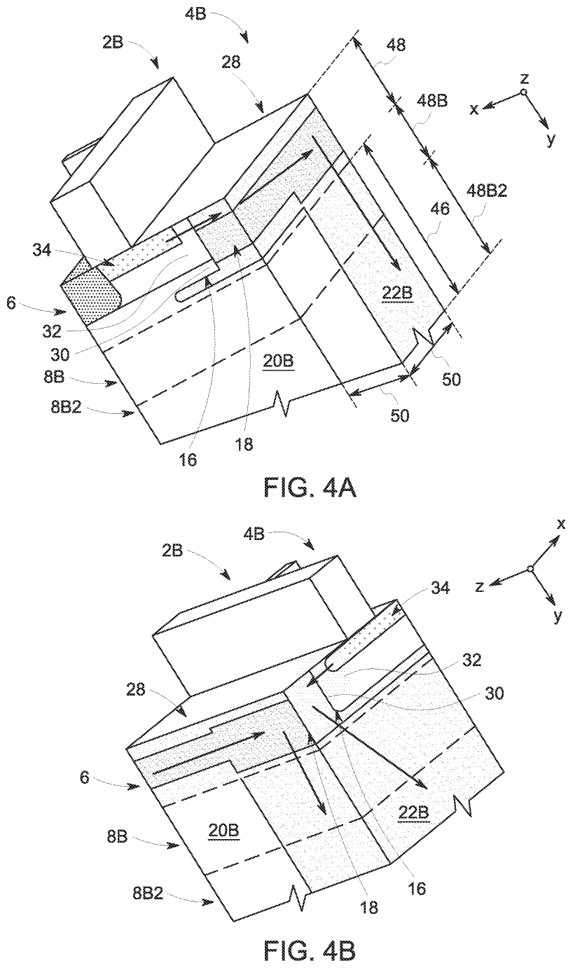

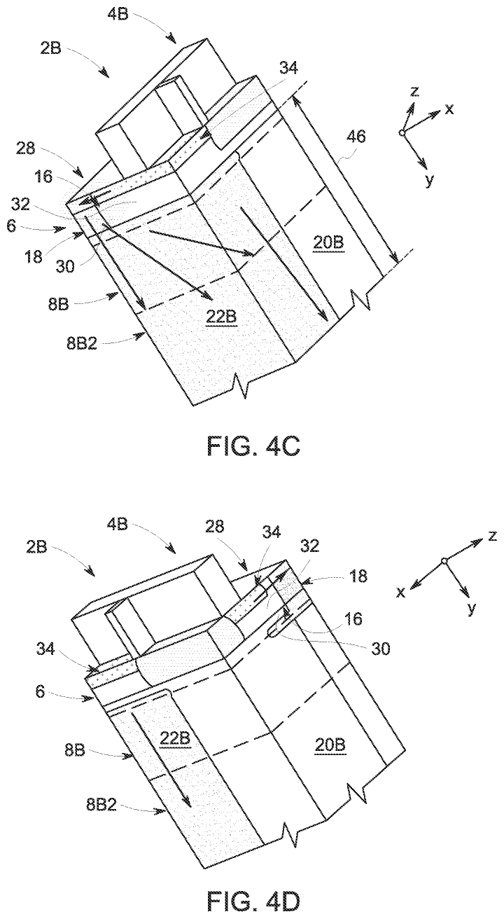

With the foregoing in mind, the embodiments described below are directed towards semiconductor power conversion device designs that include a device epi layer having device features of striped MOSFET device cells oriented in a first direction, and include one or more underlying SJ layers having SJ structures (e.g., SJ pillars) oriented in a second direction, wherein an angle between the first direction and the second direction is substantially between forty-five degrees and ninety degrees, inclusive. For example, FIG. 3 illustrates a top-down view of an embodiment of a portion of a semiconductor power conversion device 2B including a number of striped MOSFET device cells 4B. Additionally, FIGS. 4A, 4B, 4C, and 4D are respective three-dimensional (3D) cross-sections of the embodiment of the portion of the semiconductor power conversion device 2B of FIG. 3.

As illustrated in FIG. 3, the power conversion device 2B includes a device epi layer 6 and an underlying SJ layer 8B. In particular, a first section 40 (e.g., the right-most section) of FIG. 3 illustrates various device structures (e.g., surface structures) of the device epi layer 6, a second section 42 (e.g., the bottom-most section) of FIG. 3 illustrates a SJ structure 10B of the underlying SJ layer 8B, and a third section 44 (e.g., the middle section) of FIG. 3 illustrates both the device structures of the device epi layer 6 and the SJ structure 10B of the underlying SJ layer 8B. The device structures of the device epi layer 6 are illustrated as being partially transparent in the third section 44 in order to illustrate the alignment between the SJ structure 10B of the underlying SJ layer 8B with the device structures of the device epi layer 6.

The device structures of the device epi layer 6 of each striped MOSFET device cell 4B include respective contact regions 14, respective channel regions 16, and respective JFET regions 18. It may be appreciated that the contact regions 14, the channel regions 16, and the JFET regions 18 are formed as continuous stripes along the surface of the striped MOSFET device cells 4B. Additionally, the SJ structure 10B of the underlying SJ layer 8B below each striped MOSFET device cell 4B includes a first set of implanted SJ pillars 20B oppositely doped relative to a second set of implanted SJ pillars 22B. As illustrated in FIG. 3, the features of the striped MOSFET device cells 4B disposed in the device epi layer 6 extend in a first direction (i.e., along the x-axis), and the SJ pillars 20B and 22B of the underlying SJ layer 8B extend in a second direction (i.e., transverse the first direction). In particular, an angle 46 between the first direction and the second direction is substantially ninety degrees. That is, while disposed in different x-z planes, the features of the striped MOSFET device cells 4B (e.g., the contact regions, 14, the channel regions 16, and the JFET regions 18) are oriented substantially orthogonally to the SJ pillars 20B and 22B within the semiconductor power conversion device 2B.

Although FIGS. 3 and 4 illustrate that the angle 46 between the first direction (e.g., along a dimension 24 of the semiconductor power conversion device 2B) and the second direction (e.g., along a dimension 26 of the semiconductor power conversion device 2B) is substantially ninety degrees, it should be understood that, in other embodiments, the angle 46 may be disposed at any other suitable angle between forty-five degrees and ninety degrees, inclusive. In certain embodiments, the angle 46 may substantially be between fifty degrees and ninety degrees, inclusive; sixty degrees and ninety degrees, inclusive; sixty-five degrees and ninety degrees, inclusive; seventy degrees and ninety degrees, inclusive; seventy-five degrees and ninety degrees, inclusive; eighty degrees and ninety degrees, inclusive; eighty-five degrees and ninety degrees, inclusive; or the like. Additionally, in certain embodiments, the dimension 24 of the semiconductor power conversion device 2B is the greatest dimension of the SJ pillars 20B, 22B and is oriented in the first direction. The dimension 26 of the semiconductor power conversion device 2B may also be the greatest dimension of the device structures and is oriented in the second direction. In any case, a pitch 38B of the semiconductor power conversion device 2B is reduced (e.g., between subsequent device structures, such as the contact regions 14, the channel regions 16, the JFET regions 18, and the source contacts 34), as compared to the pitch 38A of the device epi layer 6 of the typical semiconductor power conversion device 2A described above, thereby increasing the channel density of the semiconductor power conversion device 2B and decreasing the on-state resistance of the semiconductor power conversion device 2B. In one embodiment, for example, the pitch 38B of the device epi layer 6 of the semiconductor power conversion device 2B may be reduced by more than thirty-three percent as compared to the pitch 38A of the device epi layer 6 of the typical semiconductor power conversion device 2A.

As mentioned above, during an on-state operation of the striped MOSFET device cell 4B (e.g., for a p-channel MOSFET device cell), current flows from the source contact 34 of the striped MOSFET device cell 4B to the drain contact 36 (not shown) of the striped MOSFET device cell 4B. As illustrated in FIGS. 3 and 4A-4D, with respect to a channel region 14 over an implanted SJ pillar 20B having the first conductivity type (e.g., p-type SJ pillar 20B), the current flows laterally from the source contact 34 to the channel region 16 along the top surface 28 of the striped MOSFET device cell 4B, the current flows laterally from the channel region 16 into an implanted SJ pillar 22B having the second conductivity type (e.g., a n-type SJ pillar 22B), and the current flows vertically from the implanted SJ pillar 22B to the drain contact 36 of the striped MOSFET device cell 4B. Additionally, with respect to a channel region 14 over an implanted SJ pillar 22B having the second conductivity type (e.g., a n-type SJ pillar 22B), the current flows laterally from the source contact 34 to the channel region 16 along the top surface 28 of the striped MOSFET device cell 4B, the current flows vertically from the channel region 16 into the implanted SJ pillar 22B to the drain contact 36 of the striped MOSFET device cell 4B. Further, it should be noted that, for a n-channel MOSFET device cell, the current may flow from the drain contact 36 (not shown) of the striped MOSFET device cell 4B to the source contact 34 of the striped MOSFET device cell 4B. That is, the current may flow in the opposite direction with respect to the current described above during an on-state operation of a p-channel MOSFET device cell.

As illustrated in FIGS. 4A-4D, the semiconductor power conversion device 2B includes a number of epi layers in which the striped MOSFET device cells 4B are defined. These include device epi layer 6 and underlying SJ layers 8B, 8B2. While the illustrated embodiment includes three epi layers, in other embodiments, the semiconductor power conversion device 2B may include any suitable number of epi layers (e.g., two, three, four, five, six, or more) to yield a device having a particular desired voltage rating. The epi layers may be fabricated using repeated cycles of epitaxial overgrowth. As illustrated in FIGS. 4A-4D, the SJ layer 8B is formed and disposed directly on the SJ layer 8B2, and the device epi layer 6 is formed and disposed directly on the SJ layer 8B. Although not illustrated in FIGS. 4A-4D, the SJ layer 8B2 may be formed and disposed directly on the substrate layer 35 having the drain contact 36. In some embodiments, the semiconductor power conversion device 2B may include additional epi layers, including any suitable number of SJ layers, intervening between the device epi layer 6 and the SJ layer 8B and/or disposed below the SJ layer 8B.

It may be appreciated that, in order to more clearly illustrate certain components of the semiconductor power conversion device 2B, certain commonly understood design elements (e.g., top metallization, passivation, and so forth) may be omitted. It may also be appreciated that, while the semiconductor power conversion device 2B is described herein in the context of a SiC-SJ device, in other embodiments, other wide band gap materials (e.g., germanium (Ge), aluminum nitride (AlN), gallium nitride (GaN), boron nitride, gallium arsenide (GaAs), diamond (C), etc.) may be used, in accordance with the present disclosure.

In some embodiments, the first set of SJ pillars 20B are doped with boron, aluminum, or another suitable p-type dopant, while the second set of SJ pillars 22B are doped with nitrogen, phosphorous, or another suitable n-type dopants, or vice versa. As mentioned above, the SJ structure 10B of the underlying SJ layer 8B below each striped MOSFET device cell 4B includes the first set of implanted SJ pillars 20B and the second set of implanted SJ pillars 22B in one or more epi layers (i.e., SJ layers 8B, 8B2). However, it should be understood that, in certain embodiments, one or more of the SJ layers may include no implanted SJ pillars, two sets of implanted SJ pillars, three sets of implanted SJ pillars, four sets of implanted SJ pillars, or the like.

In any case, the dopant concentration in the first set of SJ pillars 20B and in the second set of SJ pillars 22B is approximately the same (e.g., ±3%, ±2%, ±1%). For example, in some embodiments, each of the first set of SJ pillars 20B and each of the second set of SJ pillars 22B may have a dopant concentration greater than 5×10¹⁵ cm⁻³ and/or less than 1×10¹⁷ cm⁻³. In some embodiments, the first set of SJ pillars 20B and the second set of SJ pillars 22B are each generally designed to substantially deplete and to generally provide similar amounts (e.g., substantially equal amounts) of effective charge (e.g., per cm², normalized to device active area 5) from ionized dopants under reverse bias. Accordingly, the illustrated super-junction structure allows the striped MOSFET device cell 4B to achieve high breakdown voltage and low on-state resistance, since the p-type semiconductor portions and the n-type semiconductor portions are both substantially (e.g., completely) depleted under nominal blocking conditions.

Each epi layer 6, 8B, 8B2 has a respective thickness 48, 48B, 48B2, which may be the same or different, in certain embodiments. For instance, in certain embodiments, the thickness 48, 48B, 48B2 of each epi layer 6, 8B, 8B2 may be between 2 microns (μm) and 15 μm (e.g., 10 μm or 12 μm). Additionally, the first set of implanted SJ pillars 20B and the second set of implanted SJ pillars 22B in the SJ structure 10B have a particular depth 46 (e.g., extending along the y-axis). It should be appreciated that, in some embodiments, the depth 46 of the SJ pillars 20B, 22B may be the same between the first set of SJ pillars 20B and the second set of SJ pillars 22B. In some embodiments, for example, each of the SJ pillars 20B, 22B may extend through the entire thickness of the SJ layer 8B and may contact (e.g., electrically couple to) the adjacent layer 8B2 (e.g., an additional epi layer or a substrate layer). Alternatively, each of the SJ pillars 20B, 22B may not extend through the entire thickness of the SJ layer 8B, leaving a gap (e.g., a region of epi doping) between the SJ pillars 20B, 22B and the adjacent layer. Moreover, in some embodiments, the SJ pillar 20B, 22B may contact (e.g., electrically couple to) at least one other SJ layer pillar having a like conductivity type in an adjacent SJ layer.

Further, the depth 46 of the SJ pillars 20B, 22B may be different in different SJ layers 8B, 8B2 of the SJ structure 10B. In certain embodiments, the first set of SJ pillars 20B and the second set of SJ pillars 22B in the SJ layer 8BB may extend through the entire thickness of the SJ structure 10B. By extending through the thickness of the SJ structure 10B, continuous, vertical SJ pillars 20B, 22B may be formed from each of the SJ layers 8B, 8B2 in the SJ structure 10B. The continuous, vertical SJ pillars 20B, 22B may then provide low conduction losses and high blocking voltages.

With respect to dimensions, each of the SJ pillars 20B, 22B may have a particular width 50. In certain embodiments, the dimensions (e.g., width 50) of the SJ pillars 20B, 22B may vary along the y-axis. Moreover, the dimensions of the first set of SJ pillars 20B may vary with respect to the dimensions of the second set of SJ pillars 22B. Further, the SJ pillars 20B, 22B may have different cross-sectional shapes (e.g., defined by the set of masks used during implantation). However, the dimensions of the SJ pillars 20B, 22B in the SJ layer 8B generally match the dimensions of corresponding SJ pillars in the other SJ layers 8B2 (e.g., adjacent SJ layers). Accordingly, the SJ pillars 20B, 22B and the corresponding SJ pillars of each SJ layers are in alignment with each other.

Further, it should be appreciated that the doping of the epi layers (e.g., device epi layer 6), the doping of the SJ pillars 20B, 22B, the thicknesses of the epi layers (e.g., device epi layer 6), the depth of the SJ pillars 20B, 22B, and the width of the SJ pillars 20B, 22B may be varied for different embodiments to enable desired electrical performance (e.g., desired breakdown voltage) of the semiconductor power conversion device 2B. For example, in some embodiments, certain device parameters may be selected to provide a breakdown voltage of the semiconductor power conversion device 2B that is between approximately 1 kilovolt (kV) and 10 kV, 1 kV and 5 kV, or any other suitable range. Further, in some embodiments, the dopant concentration of the SJ pillars 20B, 22B may be between approximately 5×10¹⁵ cm⁻³ and approximately 1×10¹⁷ cm⁻³. Moreover, in some embodiments, the semiconductor power conversion device 2B may include fewer or additional SJ layers (e.g., two SJ layers, three SJ layers, four SJ layers, and/or the like) to achieve a desired voltage rating, for example.

Fabricating continuous, vertical SJ pillars that extend through the thickness of one or more epi layers (e.g., SJ layers 8B, 8B2) may be challenging for certain semiconductor materials having low diffusion coefficients of dopants. For example, fabricating such SJ pillars 20B, 22B may be challenging for embodiments in which the epi layers are fabricated from SiC, which has lower diffusion coefficients for dopants compared to silicon (Si). For example, in order to form SJ pillars 20B, 22B that, at least in some cases, extend through the entire thickness of one or more epi layers, as present in a full SJ device, numerous (e.g., 10+) thin epitaxial growth/shallow ion implantation steps may be performed. Moreover, a combination of low energy implantation (e.g., implant acceleration energies less than 0.5 mega-electron volts (MeV)) and high energy implantation (e.g., implant acceleration energies greater than 0.5 MeV) may be used to implant the SJ pillars 20B, 22B. For example, implant acceleration energies greater than 0.1 MeV and/or less than 50 MeV may be used. For instance, in some embodiments, an implant acceleration energy between 0.1 MeV and 30 MeV may be employed. Accordingly, the projected range (e.g., the penetration depth) of most commonly used SiC dopants (e.g., boron, nitrogen, phosphorus, aluminum) is approximately between 2 microns (μm) and 15 μm, which is at least suitable for implantation of the SJ pillars 20B, 22B through epi layers having a thickness between 2 μm and 15 μm. Further, in some embodiments, a suitable high energy masking material (e.g., silicon on insulator (SOI), polysilicon, thick silicon oxide, and high-Z metals) may be employed during the implantation of the SJ pillars 20B, 22B, as described in greater detail below.

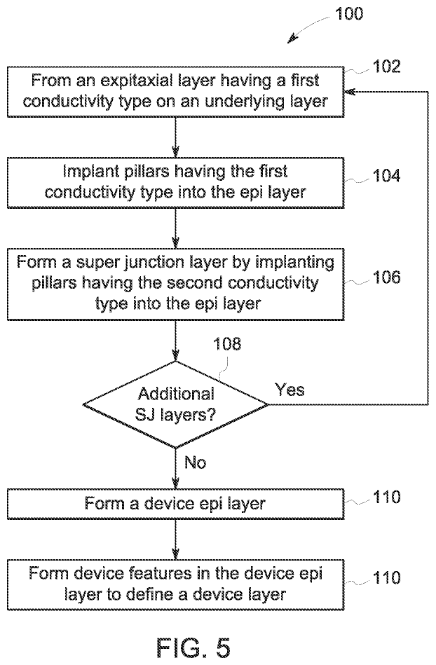

With the foregoing in mind, FIG. 5 is a flow chart of a process 100 for manufacturing an embodiment of the semiconductor power conversion device 2B including a number of striped MOSFET device cells 4B. In particular, the power conversion device 2B includes a device epi layer 6 and an underlying SJ layer 8B. As described above, the features of the striped MOSFET device cells 4B disposed in the device epi layer 6 extend in a first direction (i.e., along the x-axis), and the SJ pillars 20B and 22B of the underlying SJ layer 8B extend in a second direction (i.e., transverse the first direction). In particular, the angle 46 between the first direction and the second direction is substantially between forty-five degrees and ninety degrees, inclusive. Although the following description of the process 100 is described in a particular order, which represents a particular embodiment, it should be noted that the process 100 may be performed in any suitable order. Further, certain steps may be repeated or skipped altogether, and additional steps may be included in the process 100 in other embodiments.

The illustrated process begins with forming (process block 102) an epi layer having a particular epi doping concentration of a first conductivity type on an underlying layer. In some embodiments, the underlying layer may include a semiconductor substrate layer. As described above, the substrate layer may be made of silicon, silicon carbide (SiC), gallium nitride, diamond, aluminum nitride, boron nitride, or any other suitable wide band gap substrate. Alternatively, the epi layer may be formed on another epi layer and/or a SJ layer, as described in greater detail below.

To form the first epi layer on the underlying layer, the epi layer may be grown using chemical vapor deposition (CVD). However, in some embodiments, the epi layer may be grown onto the underlying layer using any suitable technique. The epi layer may be formed from one or more wide band gap semiconductor materials, such as silicon carbide, gallium nitride, diamond, aluminum nitride, and/or boron nitride. Further, as discussed above, the epi layer may have a first conductivity type (e.g., n-type) and a low dopant concentration relative to other regions of the semiconductor power conversion device 2B (e.g., the SJ pillars 20B, 22B or the like).

Turning back to FIG. 5, after the first epi layer is formed on the underlying layer, the illustrated process proceeds with implanting (process block 104) pillars of a first conductivity type into the first epi layer. More specifically, to form the SJ layer, the first set of SJ pillars 20B having the first conductivity type may be implanted within the first epi layer. In certain embodiments, the implanted regions of the first conductivity type (e.g., n-type) may extend through the thickness of the first epi layer. Accordingly, in some embodiments, the regions of the first conductivity type may be implanted using a suitable high energy ion implantation technique. As such, each of the one or more regions may be implanted to a depth greater than 1 μm (e.g., to depths of 2 μm to 15 μm) within the epi layer. Moreover, an implantation energy greater than 500 keV and/or less than 50 MeV may be used to implant each of the one or more regions. As such, a high energy implantation mask (e.g., silicon on insulator (SOI), polysilicon, thick silicon oxide, high-Z metals such as platinum, molybdenum, gold) may be used in conjunction with the high energy ion implantation. Moreover, the mask may be formed using any suitable technique. That is, for example, the mask may be deposited, grown, and/or coated directly onto the portion of the epi layer. Furthermore, once the mask material has been deposited on the surface of the epi layer, the mask may be formed by patterning (e.g., lithographically patterning) the mask material to expose or uncover a portion of the epi layer. The first set of SJ pillars 20B may then be selectively implanted through the exposed portion of the epi layer.

Additionally, to form the SJ layer, the second set of SJ pillars 22B of the second conductivity type (e.g., p-type) is implanted (process block 106) within the first epi layer. In some embodiments, the SJ layer may be formed using a method of self-alignment and a set of masks, as described in U.S. Pat. No. 10,636,660, entitled, “SUPER-JUNCTION SEMICONDUCTOR DEVICE FABRICATION,” filed Dec. 20, 2018, the disclosure of which is incorporated by reference herein in its entirety for all purposes. For example, after implanting the first set of SJ pillars 20B into a first portion of the epi layer using a first mask, as described above, which covers a second portion of the epi layer, a second mask may be formed that is self-aligned relative to the first mask on the first portion of the epi layer. In some embodiments, the second mask may be formed to have different physical and/or chemical properties relative to the first mask. For instance, the second mask may be formed from a different material, may undergo different chemical and/or physical alterations, and/or may be formed with different optical properties and/or wavelength absorption properties relative to the first mask. Accordingly, the first mask may then be removed by a suitable process (e.g., dissolved, stripped, and/or degraded) that leaves the second mask intact. By removing the first mask, the second portion of the epi layer is exposed, while the first portion of the epi layer remains masked by the second mask. Thus, the second set of SJ pillars 22B may be selectively implanted into the second portion of the epi layer, and the second mask may then be removed. More specifically, in some embodiments, the second set of SJ pillars 22B may be implanted adjacent to and interleaved between the first set of SJ pillars 20B. For embodiment in which the first and second mask are self-aligned, misalignment (e.g., overlap and/or gaps) between the first set of SJ pillars 20B and the second set of SJ pillars 22B, which can disrupt the uniformity of the electrical field and reduce the maximum blocking voltage of the semiconductor power conversion device 2B, may be reduced or avoided.

Further, the set of SJ pillars 20B, 22B may be implanted using any suitable technique (e.g., high energy implant, lower energy implant), as discussed below. For instance, in some embodiments, the set of SJ pillars 20B, 22B may be implanted with standard low energy implantation techniques. For example, the set of SJ pillars 20B, 22B may be implanted to a depth less than or equal to 1 μm. Accordingly, an implantation energy less than 500 keV may be used to implant each of the SJ pillars 20B, 22B. However, in some embodiments, the set of SJ pillars 20B, 22B may be implanted using a suitable high energy ion implantation technique. Accordingly, an implantation energy greater than 500 keV and/or less than 50 MeV may be used to implant each of the SJ pillars 20B, 22B. Moreover, the masks described above may be a high energy implantation mask (e.g., silicon on insulator (SOI), polysilicon, thick silicon oxide, high-Z metals) used in conjunction with the high energy ion implantation.

To form a suitable number of SJ layers in the semiconductor power conversion device 2B, a portion of the process 100 (e.g., process block 102, process block 104, and/or process block 106) may be repeated one or more times. Accordingly, after the SJ layer is formed, the process 100 may proceed with determining (decision block 108) whether an additional SJ layer will be added to the semiconductor power conversion device 2B. In embodiments having one or more additional SJ layers, for example, a second epi layer may be formed (process block 102) on the previously implanted SJ layer and a second SJ layer may be formed (e.g., process block 104, process block 106).

After completing fabrication of the one or more SJ layers, the process 100 illustrated in FIG. 5 proceeds with forming (process block 110) a device epi layer 6 having the particular epi doping concentration of the first conductivity type. As discussed with reference to the formation of the one or more epi layers of the SJ layers (process block 102), the device epi layer 6 may be grown using CVD. Alternatively, the device epi layer 6 may be formed on the one or more underlying SJ layers using any suitable technique. The device epi layer 6 may also be formed from one or more wide band gap semiconductor materials, such as silicon carbide, gallium nitride, diamond, aluminum nitride, and/or boron nitride.

The process 100 illustrated in FIG. 5 then proceeds with forming (process block 112) certain device features within the device epi layer 6 to define a device layer. That is, for example, the device features (e.g., the contact regions 14, the channel regions 16, the JFET regions 18, the well regions 30, the source regions 32, the source contacts 34, and the like) are implanted in the device epi layer 6 such that the device features are oriented in a first direction, the SJ structures (e.g., SJ pillars) are oriented in a second direction, and an angle between the first direction and the second direction is substantially between forty-five degrees and ninety degrees, inclusive. In some embodiments, the device features may be implanted using the method of self-alignment and the set of masks, as described above. Accordingly, while the process block 110 is described herein as a single step, it may be appreciated that forming the device features may constitute multiple steps, such as a separate implantation step for each respective feature and/or multiple implantation steps for each feature.

It may be appreciated that, for certain embodiments, the epi layers of the semiconductor power conversion device 2B may be formed with the lowest controllable doping level, for example, without any intentional epi doping (e.g., without intentionally introducing any dopants) or at minimal doping level that allows control of the type (n or p) within specified low concentration range. However, it is recognized since impurities, such as nitrogen, may be present in machinery and/or tools used during the epitaxial growth process, the epi layers may still include a low amount of epi doping (e.g., of the first conductivity type, n-type), which is referred to herein a “minimized epi doping concentration.” Accordingly, while the epi layers may be formed with no intentional doping concentration, the actual epi doping concentration of epi layers may be generally 8.0×10¹³ cm⁻³ or more, depending on the equipment used for epitaxial growth. For example, in certain embodiments discussed below, the minimized epi doping concentration of the first conductivity type (e.g., n-type) may be less than 3.0×10¹⁵ cm⁻³, less than 2×10¹⁵ cm⁻³, less than 1×10¹⁵ cm⁻³, or between 8×10¹³ cm⁻³ and 2×10¹⁵ cm⁻³. For example, when the first conductivity type is n-type, nitrogen, phosphorous, arsenic, antimony, and/or the like may be used as the dopant. Alternatively, when the first conductivity type is p-type, boron, aluminum, and/or the like may be used as the dopant.

Technical effects of the present approach include semiconductor power conversion device designs that include a device epitaxial (epi) layer having device features of striped MOSFET device cells oriented in a first direction, and include one or more underlying SJ layers having SJ structures (e.g., SJ pillars) oriented in a second direction, wherein an angle between the first direction and the second direction is substantially between forty-five degrees and ninety degrees, inclusive. For instance, in one embodiment, the surface features of the device epi layer may be oriented substantially orthogonally (e.g., at a ninety degree angle) to the SJ structures of the one or more underlying SJ layers. In this way, a pitch of the semiconductor power conversion device is reduced, as compared to a pitch of a semiconductor power conversion device in which the surface features of the striped MOSFET device cells are oriented in the same direction as (e.g., oriented parallel to) the SJ structures of the one or more underlying SJ layers. As such, a channel density of the semiconductor power conversion device is increased, thereby decreasing the on-state resistance of the semiconductor power conversion device during an on-state operation.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A semiconductor device, comprising:
a first epitaxial (epi) layer that forms a first super-junction (SJ) layer of the semiconductor device, wherein the first epi layer includes oppositely doped SJ pillars that extend along a first direction within the SJ layer; and
a second epi layer disposed on the first SJ layer that forms a device layer of the semiconductor device, wherein the device layer includes device structures of a striped metal-oxide-semiconductor field-effect transistor (MOSFET) device cell that extends along a second direction within the device layer, wherein an angle between the first direction and the second direction is substantially between forty-five degrees and ninety degrees, inclusive.

2. The semiconductor device of claim 1, wherein the angle between the first direction and the second direction is substantially ninety degrees.

3. The semiconductor device of claim 1, wherein the angle between the first direction and the second direction is substantially between eighty degrees and ninety degrees, inclusive.

4. The semiconductor device of claim 1, wherein the device structures comprise one or more of: a contact region of the striped MOSFET device cell, a source contact of the contact region, a channel region of the striped MOSFET device cell, and a junction field-effect transistor (JFET) region of the striped MOSFET device cell.

5. The semiconductor device of claim 1, wherein a greatest dimension of the SJ pillars is oriented in the first direction, and wherein a greatest dimension of the device structures is oriented in the second direction.

6. The semiconductor device of claim 1, wherein the first direction is transverse to the second direction.

7. The semiconductor device of claim 1, wherein the striped MOSFET device cell is a planar, striped MOSFET device cell.

8. The semiconductor device of claim 1, wherein the striped MOSFET device cell is a trench, striped MOSFET device cell.

9. A method of fabricating a semiconductor device, comprising:
forming a first super-junction (SJ) layer of the semiconductor device by:
forming a first epitaxial (epi) layer on an underlying layer;
implanting the first epi layer with a first set of SJ pillars to have a particular doping concentration of a first conductivity type; and
implanting the first epi layer with a second set of SJ pillars to have the particular doping concentration of a second conductivity type, wherein the first set of SJ pillars and the second set of SJ pillars extend along a first direction within the SJ layer; and
forming a device layer of the semiconductor device by:
forming a second epi layer on the first SJ layer; and
forming device structures of a plurality of striped metal-oxide-semiconductor field-effect transistor (MOSFET) device cells in the device layer that extend along a second direction within the device layer, wherein an angle between the first direction and the second direction is substantially between forty-five degrees and ninety degrees, inclusive.

10. The method of manufacturing the semiconductor device of claim 9, wherein the first direction is transverse to the second direction.

11. The method of manufacturing the semiconductor device of claim 9, wherein the angle between the first direction and the second direction is substantially ninety degrees.

12. The method of manufacturing the semiconductor device of claim 9, wherein the device structures comprise one or more of: respective contact regions of the plurality of striped MOSFET device cells, respective channel regions of the plurality of striped MOSFET device cells, and respective junction field-effect transistor (JFET) regions of the striped MOSFET device cells.

13. The method of manufacturing the semiconductor device of claim 9, wherein the one or more device structures comprise respective source contacts of the plurality of striped MOSFET device cells.

14. A semiconductor device, comprising:
a first epitaxial (epi) layer that forms a first super-junction (SJ) layer of the semiconductor device, wherein the first epi layer includes a first set of SJ pillars having a particular doping concentration of the first conductivity type and a second set of SJ pillars having the particular doping concentration of the second conductivity type, wherein the first set of SJ pillars and the second set of SJ pillars extend along a first direction within the SJ layer; and
a second epi layer disposed on the first SJ layer that forms a device layer of the semiconductor device, wherein the device layer includes device structures of a plurality of striped metal-oxide-semiconductor field-effect transistor (MOSFET) device cells that extend along a second direction within the device layer, wherein an angle between the first direction and the second direction is substantially between forty-five degrees and ninety degrees, inclusive.

15. The semiconductor device of claim 14, wherein the angle between the first direction and the second direction is substantially ninety degrees.

16. The semiconductor device of claim 14, wherein the device structures comprise one or more of: respective contact regions of the plurality of striped MOSFET device cells, respective source contacts of the respective contact regions, respective channel regions of the plurality of striped MOSFET device cells, and respective junction field-effect transistor (JFET) regions of the striped MOSFET device cells.

17. The semiconductor device of claim 15, wherein the plurality of striped MOSFET device cells include a planar, striped MOSFET device cell.

18. The semiconductor device of claim 15, wherein the plurality of striped MOSFET device cells includes a trench, striped MOSFET device cell.

19. The semiconductor device of claim 14, wherein the semiconductor device is a semiconductor power conversion device.

20. The semiconductor device of claim 14, wherein the semiconductor device is a silicon carbide (SiC) power conversion device.
